(19) United States
(12) Patent Application Publication
(10) Pub. No.: US 2002/0175400 A1
(43) Pub. Date: Nov. 28, 2002

(54) Semiconductor device and method of formation

(76) Inventors: Mark A. Gerber, Austin, TX (US); Shawn M. O'Connor, Austin, TX (US); Trent A. Thompson, Austin, TX (US)

Correspondence Address: Motorola, Inc, Austin Intellectual Property Law Section, 7700 West Parmer Lane, MD: TX32/PL02, Austin, TX, 78729, US

(21) Appl. No.: 09/865,854

(22) Filed: May 26, 2001

(51) Int. Cl. H01L 23/06; H01L 23/48; H01L 21/44; H01L 21/48; H01L 21/50; H01L 21/30; H01L 21/46; H01L 23/02; H01L 23/34; H01L 29/40; H01L 23/52

(52) U.S. Cl. 257/686; 257/685; 257/684; 257/723; 257/783; 257/786; 257/784; 438/455; 438/109; 438/118; 438/617

(57) ABSTRACT

A semiconductor device and its method of formation are disclosed wherein a first semiconductor substrate (20) and a second semiconductor substrate (21) are encapsulated in a no lead package (100). In some embodiments, a plurality of off die bond pads (30) is coupled to at least one of the first and second semiconductor substrates (20, 21). In some embodiments, the first semiconductor substrate (20) has a backside (40) which remains exposed after encapsulation.

### FIELD OF THE INVENTION

The invention relates generally to semiconductor devices and more particularly to a no lead package.

### BACKGROUND

Many semiconductor devices have leads that form the electrical connection from the package to the printed circuit board, such as the quad flat package. One disadvantage is that the leads can easily be damaged or bent which would render the connection to the board unreliable. Additionally, such packages have a high inductance caused by the length of the leads. Another problem is that the leads extending from the package increase the size of the semiconductor device. As handheld products, such as cellular phones and pagers, decrease in size and more semiconductor devices are being used in various products, there is a desire to decrease the size of semiconductor devices for many applications in order to reduce printed circuit board space.

### BRIEF DESCRIPTION OF THE DRAWINGS

The present invention is illustrated by way of example and not limitation in the accompanying figures, in which like references indicate similar elements, and in which:

FIG. 1 includes an illustration of a top view of a semiconductor wafer;

FIG. 2 includes an illustration of a top view of the semiconductor wafer of FIG. 1 wherein the semiconductor wafer is attached to a wafer mount tape carrier;

FIG. 3 includes an illustration of a top view of a leadframe with a plurality of semiconductor substrates provided thereon;

FIG. 4 includes an illustration of a top view of the leadframe of FIG. 3, further showing a first semiconductor substrate and a second semiconductor substrate;

FIG. 5 includes an illustration of a cross-sectional view of the leadframe of FIG. 3, further showing a first semiconductor substrate and a second semiconductor substrate over;

FIG. 6 includes an illustration of a cross-sectional view of the semiconductor device of FIG. 5 further a substantially completed semiconductor device.

FIG. 7 includes an illustration of a cross-sectional view of a no lead package with stacked die in accordance with one embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Keeping device dimensions as small as possible is not only important to single chip devices, but to multiple chip devices as well. Therefore, a need exists for a small multiple chip device with low inductance and high reliability. Additionally, manufacturers are also driven to maintain a low cost for manufacturing the semiconductor devices.

Multiple die are stacked in packages to form semiconductor devices. The stacking of multiple die in a no lead package is desirable because such a package decreases inductance, overall package size, and cost comparable to other stacked die packages. One low-cost and reliable exposed pad electrical carrier is the quad flat no lead package (QFN), also referred to as the microleadframe package(MLF) and bump chip carrier (BCC). In one embodiment, two die in a QFN package are stacked on top of each other. Wirebonds, solder or an adhesive can electrically couple the dies. The invention is better understood by turning to the figures and is defined by the claims.

A semiconductor wafer 10 including a plurality of dies or first semiconductor substrates 20 and a plurality of scribe lines 22 that separate the multiple first semiconductor substrates 20 from each other is shown in FIG. 1. Only a few of the die and scribe lines are labeled for simplicity. A skilled artisan knows that die on a semiconductor wafer are separated on all sides by scribe lines. Each first semiconductor substrate 20 of semiconductor wafer 10 has completed a semiconductor process flow up to and including deposition of a passivation layer. Each first semiconductor substrate 20 also contains a plurality of devices formed on a semiconductor substrate such as a silicon substrate. In another embodiment the semiconductor wafer 10 can be gallium arsenide, silicon on insulator (SOI) or the like. The diameter of semiconductor wafer 10 can be any desired diameter such as approximately 67 mm, 133 mm and 200 mm or the like.

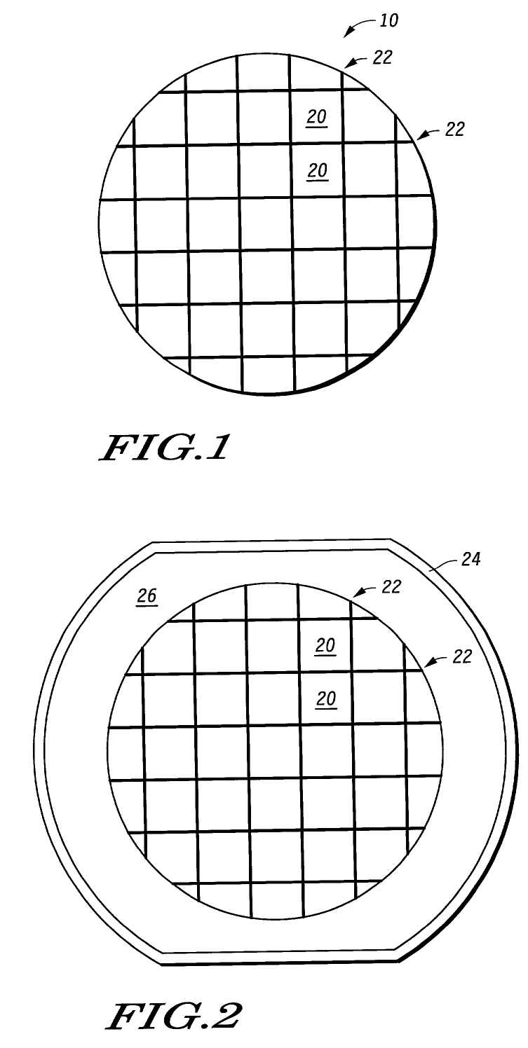

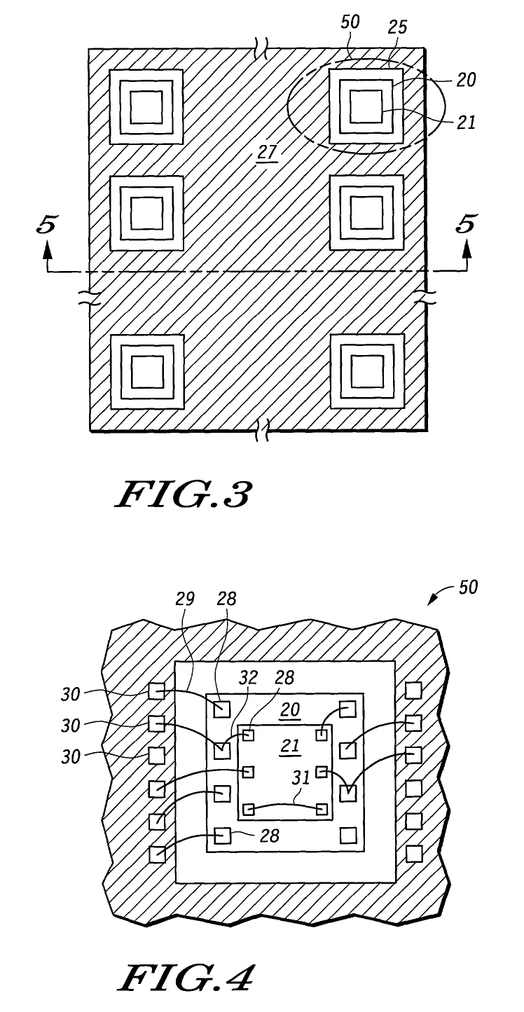

The semiconductor wafer 10 is attached to a first tape 26 which previously has been attached to a wafer mount tape carrier 24, as shown in FIG. 2. A wafer dicing process is performed next by cutting semiconductor wafer 10 along the scribe lines 22 in both the X and Y directions. Afterwards, the first semiconductor substrates 20 are removed from the first tape 26 and are placed within receiving areas 25 on a leadframe 27, illustrated in FIG. 3. The leadframe 27 can be any conductive material such as an alloy including nickel and iron, nickel palladium and the like. The leadframe 27 can be purchased as a patterned leadframe with off die bond pads already formed in a desired pattern, such as a staggered array of bond pads. If leadframe 27 is not purchased with the desired formation of the off die bond pads, the off die bond pads can be formed by patterning and etching the leadframe 27 by applying a polymer tape as a mask layer. After etching the leadframe 27 with a wet chemistry selective to the leadframe material and not the polymer tape, the mask layer is mechanically removed. In a preferred embodiment, a human removes the mask layer by pulling the tape off the leadframe 27.

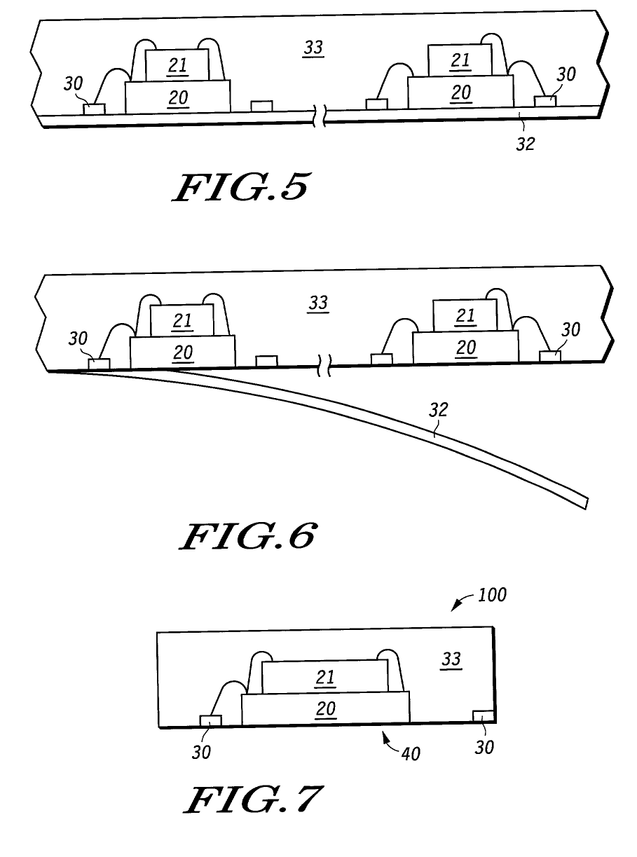

Underneath the patterned leadframe 27 is a second tape (not shown), which will be discussed below in more detail in regards to FIGS. 5-6. If the leadframe 27 is etched during the process flow, the second tape is added after the etch process. The receiving area 25, in a preferred embodiment, is an open window within leadframe 27 so that when first semiconductor substrate 20 is placed on leadframe 27 it is attached to the underlying second tape. In an alternate embodiment, the receiving area 25 contains a portion of the leadframe 27 patterned into different shapes. For example, the leadframe 27 may be patterned to be “X-shaped” within the receiving area 25. In another embodiment, there is no opening in the in the receiving area 25. Thus, the receiving area is completely filled by the leadframe 27. Additionally, the receiving area 25 may be elevated relative to the other areas of the leadframe 27. If receiving area 25 includes at least a portion of leadframe 27, then an adhesive may be needed to attach first semiconductor substrate 20 to the receiving area 25. (In an embodiment where there is no leadframe 27 opening in the receiving area 25, an adhesive is needed.) In one embodiment the adhesive can be a tape and in another it can be a another adhesive material.

Afterwards, a second die or second semiconductor substrate 21 is taken from a different or the same semiconductor wafer as first semiconductor substrate 20 and attached to first semiconductor substrate 20, as shown in FIG. 3. Thus second semiconductor substrate 21 can be identical to first semiconductor substrate 20. In a preferred embodiment, the second semiconductor substrate 21 will be a die that is smaller in X and Y dimensions than first semiconductor substrate 20. However, the first semiconductor substrate 20 can be smaller, larger, or the same size as the second semiconductor substrate 21. Any adhesive used to attach first semiconductor substrate 20 to the receiving area 25 can be used to attach the second semiconductor substrate 21 to the first semiconductor substrate 20; it is not important that the same adhesive be used. One such adhesive that can be used is a tape die attach. In a preferred embodiment, a conductive epoxy is used to electrically connect first semiconductor substrate 20 to second semiconductor substrate 21. In other embodiments, the second semiconductor substrate 21 is already packaged in a flip-chip package and is bumped at this stage in the processing to first semiconductor substrate 20. In other embodiments, the second semiconductor substrate 21 is packaged in BGAs, QFPs, or the like. At least a portion of the second semiconductor substrate 21 is located over first semiconductor substrate 20.

Next, a plasma clean may be performed on leadframe 27 and the attached first semiconductor substrate 20 and second semiconductor substrate 21 in order to prepare the leadframe surface for subsequent wirebonding. In addition, the plasma clean helps to prepare the surfaces of first semiconductor substrates 20 and 21 for subsequent encapsulation with a mold compound 33. If second semiconductor substrate 21 is already packaged, then only the first semiconductor substrate 20 will be wirebonded. As shown in FIG. 4, wirebonds 29 extend from the on die bond pad 28 to the off die bond pad 30. If second semiconductor substrate 21, however, is not already packaged some of the on die bond pads 28 for second die may be bonded to each other as shown in regards to wirebond 31 or alternatively bonded to the on die bond pads 28 of the first semiconductor substrate 20 shown as wirebond 32 in FIG. 4. Therefore, an on die bond pad 28 for the first semiconductor substrate 20 may be wirebonded to the on die bond pads 28 for second semiconductor substrate 21 as well as the off die bond pads 30. The wirebonds 29, 31, and 32 are used to electrically connect the dies to each other and/or the dies to the external electrical carrier Although the off die bond pads 30 and the on die bond pads 28 are shown on only two sides of the first semiconductor substrate 20, the second semiconductor substrate 21 and the leadframe 27, as a skilled artisan knows the bond pads can be on all or at least some of the sides. In addition, the number of bond pads is shown by way of example; any number of bond pads can be used on each side.

After wirebonding, a mold compound 33, also referred to as an encapsulation 33, is applied in order to encapsulate first semiconductor substrate 20 and second semiconductor substrate 21. In a preferred embodiment mold compound 33 is a silica filled resin. However, mold compound 33 can also be a ceramic or another material. In one embodiment, the mold compound 33 is a halide-free material. FIG. 5 shows a cross-section after encapsulation and wirebonding of the first semiconductor substrate 20 and the second semiconductor substrate 21 over leadframe 27 which includes the off die bond pads 30. Additionally, the second tape 32, which is typically a polymer material is shown. At this point in the processing the second tape 32 is no longer needed to mechanically support first semiconductor substrate 20. Therefore, it is mechanically removed as is shown in FIG. 6.

The result is stacked semiconductor substrates in a package body that is no lead package 100, with a backside 40 of the first semiconductor substrate 20 exposed, as illustrated in FIG. 7. It is not necessary for the backside 40 of the first semiconductor substrate 20 to be exposed, however, backside exposure of a die has added advantages. If a die has more than three metal layers, such as five metal layers, the ability to perform failure analysis on the die by accessing the front of the die with failure analysis tools like a focused ion beam (FIB) is difficult. Grinding the backside of the die to access the desired feature from the die is advantageous, since it is easy to damage the feature being analyzed. Therefore, the package chosen needs to allow for backside access in order to allow for certain types of failure analysis on die with more than three metal layers.

In the completed no lead package 100, off die bond pads 30 are also called exposed pad electrical contacts because they serve as the electrical contact between the package and a printed circuit board, for example. The exposed pad electrical contacts 30 can be enclosed on all sides, except for the bottom, by the mold compound or 33 or can have multiple sides exposed, as shown in FIG. 7.

In the foregoing specification the invention has been described with reference to specific embodiments. However, one of ordinary skill in the art appreciates that various modifications and changes can be made without departing from the scope of the present invention as set forth in the claims below. For example, although a first semiconductor substrate 20 and a second semiconductor substrate 21 were discussed, a skilled artisan recognizes that any plurality of semiconductor substrates, such as an additional a third semiconductor substrate, can be encapsulated by the package body. Accordingly, the specification and figures are the be regarded in an illustrative rather than restrictive sense, and all such modifications are intended to be included within the scope of the present invention. Benefits, other advantages, and solutions to problems have been described with regard to specific embodiments. However, the benefits, advantages, solutions to problems, and any element(s) that may cause any benefit, advantage, or solution to occur or become more pronounced are not to be construed as a critical, required, or essential feature or element of any of the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A semiconductor device, comprising:
a first semiconductor substrate;
a second semiconductor substrate located such that at least a portion of the second semiconductor substrate is over the first semiconductor substrate; and
a package body which is a no lead package with an exposed pad electrical carrier and which encapsulates the first semiconductor substrate and the second semiconductor substrate.

2. The semiconductor device of claim 1, further comprising:
a plurality of off die bond pads, coupled to at least one of the first and second semiconductor substrates.

3. The semiconductor device of claim 1, wherein the first semiconductor substrate is electrically connected to the second semiconductor substrate.

4. The semiconductor device of claim 1, wherein the first semiconductor substrate is electrically connected to the second semiconductor substrate by way of solder.

5. The semiconductor device of claim 1, wherein the first semiconductor substrate is electrically connected to the second semiconductor substrate by way of conductive epoxy.

6. The semiconductor device of claim 1, wherein the first semiconductor substrate has a backside which remains exposed after encapsulation.

7. The semiconductor device of claim 1, wherein the package body is plastic.

8. The semiconductor device of claim 1, further comprising:
a third semiconductor substrate encapsulated by the package body.

9. The semiconductor device of claim 1, wherein encapsulation is a halide-free material.

10. The semiconductor device of claim 1, further comprising
tape die attach between the first and second semiconductor substrates.

11. A method of forming a semiconductor device, comprising:
providing a first semiconductor substrate;
providing a second semiconductor substrate; and
encapsulating the first semiconductor substrate and the second semiconductor substrate in a no lead package with an exposed pad electrical carrier.

12. The method of forming a semiconductor device as in claim 11, further comprising:
providing a patterned leadframe under the first semiconductor substrate;
etching a first portion of the patterned leadframe; and
attaching a tape to a second portion of the patterned leadframe.

13. The method of forming a semiconductor device as in claim 11, further comprising:
electrically connecting an off die bond pad to at least one of the first and second substrates.

14. The method of forming a semiconductor device as in claim 11, further comprising:
providing a patterned leadframe under the first semiconductor substrate; and
attaching a tape to the patterned leadframe, wherein the patterned leadframe comprises a plurality of off die bond pads.

15. The method of forming a semiconductor device as in claim 11, further comprising:
electrically connecting the first and second semiconductor substrates.

16. The method of forming a semiconductor device as in claim 15, further comprising:
applying a plasma to the first and second semiconductor substrates prior to electrically connecting the first and second semiconductor substrates.

17. The semiconductor device of claim 11, wherein the first semiconductor substrate has a backside which remains exposed after encapsulating.

18. A semiconductor device, comprising:
a first semiconductor substrate;
a second semiconductor; and
a package body which is a no lead package with an exposed pad electrical carrier and which encapsulates the first semiconductor substrate and the second semiconductor substrate

19. The semiconductor device of claim 18, wherein the first semiconductor substrate has a backside which remains exposed after encapsulation.

20. The semiconductor device of claim 18, further comprising:
a plurality of off die bond pads, coupled to at least one of the first and second semiconductor substrates.
